(19) United States
(12) Patent Application Publication
(10) Pub. No.: US 2016/0348274 A1
(43) Pub. Date: Dec. 1, 2016

(54) METHOD AND APPARATUS FOR MANUFACTURING SILICON CARBIDE SUBSTRATE

(71) Applicant: Sumitomo Electric Industries, Ltd., Osaka-shi (JP)

(72) Inventors: Jun GENBA, Itami-shi (JP); Taro NISHIGUCHI, Itami-shi (JP)

(21) Appl. No.: 14/724,628

(22) Filed: May 28, 2015

(51) Int. Cl. C30B 25/08; C30B 29/36; C23C 16/455; C30B 25/10; C23C 16/46; C23C 16/32

(52) U.S. Cl. CPC C30B 25/08; C23C 16/46; C23C 16/325; C23C 16/45514; C30B 25/10; C30B 29/36

(57) ABSTRACT

A method for manufacturing a silicon carbide substrate is a method for manufacturing a silicon carbide semiconductor substrate, in which epitaxial growth is carried out in a reaction chamber, and includes the steps of arranging a base substrate composed of silicon carbide in the reaction chamber and forming an epitaxially grown film on the base substrate. In the step of forming an epitaxially grown film, the base substrate is heated while a reaction gas in which a first gas containing ammonia and a second gas containing a halide but not containing ammonia have been mixed with each other is supplied toward the base substrate. The first gas is mixed with the second gas after the first gas is heated no that ammonia contained in the first gas can be thermally decomposed.

### BACKGROUND OF THE INVENTION

Field of the Invention

The present disclosure relates to a method and an apparatus for manufacturing a silicon carbide substrate.

Description of the Background Art

In order to achieve a higher breakdown voltage and lower loss of a semiconductor device, silicon carbide has recently increasingly been adopted as a material for forming a semiconductor device.

A silicon carbide substrate employed for a semiconductor device is manufactured, for example, by forming an epitaxially grown film on a base substrate composed of silicon carbide. Specifically, a silicon carbide substrate in which an epitaxially grown film is formed on a base substrate is manufactured by thermally decomposing a source gas such as silane or propane and a dopant gas such as nitrogen and causing reaction therebetween. In order to manufacture a semiconductor device higher in quality at high efficiency, a method or an apparatus for manufacturing at high efficiency, a silicon carbide substrate excellent in uniformity in impurity concentration and crystallinity is required. For example, Japanese Patent Laying-Open No. 2006-261612 discloses a method for manufacturing a silicon carbide semiconductor allowing uniform concentration of nitrogen in a surface of a substrate. For example, F. La Via et. al. “High growth rate process in a SiC horizontal CVD reactor using HCl,” MICRO ELECTRONIC ENGINEERING, January 2006, Volume 83, Issue 1, pp. 48-50 discloses improvement in rate of epitaxial growth by forming an epitaxially grown film with a reaction gas containing hydrogen chloride.

### SUMMARY OF THE INVENTION

A method for manufacturing a silicon carbide substrate according to the present disclosure is a method for manufacturing a silicon carbide semiconductor substrate, in which epitaxial growth is carried out in a reaction chamber, and includes the steps of arranging abase substrate composed of silicon carbide in the reaction chamber and forming an epitaxially grown film on the base substrate. In the step of forming an epitaxially grown film, the base substrate is heated while a reaction gas in which a first gas containing ammonia and a second gas containing a halide but not containing ammonia have been mixed with each other is supplied toward the base substrate. The first gas is mixed with the second gas after the first gas is heated so that ammonia contained in the first gas can be thermally decomposed.

An apparatus for manufacturing a silicon carbide substrate according to the present disclosure includes a reaction chamber for arranging abase substrate composed of silicon carbide in the inside thereof, a heater for heating the base substrate, and a gas supplier for supplying a reaction gas for forming an epitaxially grown film on the base substrate into the inside of the reaction chamber. The gas supplier is structured to be able to supply the reaction gas in which a first gas containing ammonia and a second gas containing, a halide but not containing ammonia have been mixed with each other into the inside of the reaction chamber. In addition, the gas supplier is structured to be able to mix the first gas with the second gas after the first gas is heated so that ammonia contained in the first gas can be thermally decomposed.

### BRIEF DESCRIPTION OF THE DRAWINGS

FIG. 1 is a schematic cross-sectional view showing a structure of an apparatus for manufacturing a silicon carbide substrate.

FIG. 2 is a flowchart schematically showing a method for manufacturing a silicon carbide substrate.

FIGS. 3 and 4 are schematic diagrams for illustrating the method for manufacturing a silicon carbide substrate.

FIG. 5 is a schematic cross-sectional view showing a structure of an apparatus for manufacturing a silicon carbide substrate according to a second embodiment

FIG. 6 is a schematic top view showing in an enlarged manner, the structure of the apparatus for manufacturing a silicon carbide substrate according to the second embodiment.

FIG. 7 is a schematic diagram showing a structure of a gas pipe in an enlarged manner.

FIG. 8 is a schematic diagram showing a structure of another gas pipe in an enlarged manner.

FIG. 9 is a schematic cross-sectional view showing a structure of an apparatus for manufacturing a silicon carbide substrate according to a third embodiment.

### DESCRIPTION OF THE PREFERRED EMBODIMENTS

### Description of Embodiments

When ammonia which is readily thermally decomposed is adopted as a dopant gas instead of nitrogen in forming an epitaxially grown film on a base substrate, an impurity concentration in a surface of a substrate can be more uniform. As disclosed in F. La Via et al., “High growth rate process in a SiC horizontal CVD reactor using HCl,” MICRO ELECTRONIC ENGINEERING, January 2006, Volume 83, Issue 1, pp. 48-50, when an epitaxially grown film is formed with a reaction gas containing such a halide as hydrogen chloride, a rate of growth can be improved and hence a silicon carbide substrate can more efficiently be manufactured. When epitaxial growth is carried out with ammonia as a dopant gas and a reaction gas containing such a halide as hydrogen chloride, however, a silicon carbide substrate uniform in impurity concentration can efficiently be manufactured, whereas crystallinity of the silicon carbide substrate is lowered.

(1) A method for manufacturing a silicon carbide substrate according to the present disclosure is a method for manufacturing a silicon carbide semiconductor substrate, in which epitaxial growth is carried out in a reaction chamber, and includes the steps of arranging a base substrate composed of silicon carbide in the reaction chamber and forming an epitaxially grown film on the base substrate. In the step of forming an epitaxially grown film, the base substrate is heated while a reaction gas in which a first gas containing ammonia and a second gas containing a halide but not containing ammonia have been mixed with each other is supplied toward the base substrate. The first gas is mixed with the second gas after the first gas s heated so that ammonia contained in the first gas can be thermally decomposed.

The present inventor has conducted detailed studies about a cause of lowering in crystallinity of a silicon carbide substrate in a case that epitaxial growth is carried out with ammonia as a dopant gas and a reaction gas containing a halide. Consequently, the present inventor has found that when ammonia and such a halide as hydrogen chloride are mixed with each other before thermal decomposition, these components react with each other to generate a solid by-product, which adheres as a foreign matter to a growing epitaxial film, and consequently crystallinity lowers, and derived the present disclosure.

In the method for manufacturing a silicon carbide substrate according to the present disclosure, a reaction gas containing ammonia which is readily thermally decomposed is employed. Therefore, a silicon carbide substrate more uniform in impurity (nitrogen atoms) concentration can be manufactured. Since a reaction gas containing a halide is employed in the method for manufacturing a silicon carbide substrate, a rate of epitaxial growth can be improved. Furthermore, in the method for manufacturing a silicon carbide substrate, a reaction gas is formed as a first gas containing ammonia is mixed with a second gas containing a halide after the first gas is heated so that ammonia contained in the first gas can be thermally decomposed. Thus, generation of a solid by-product (ammonium halide) as a result of reaction between ammonia in the first gas and a halide in the second gas before they are thermally decomposed can be suppressed. Thus, lowering in crystallinity of a silicon carbide substrate due to adhesion of the by-product to a growing epitaxial film can be suppressed. Therefore, according to the method for manufacturing a silicon carbide substrate according to the present disclosure, a silicon carbide substrate excellent in uniformity in impurity concentration and crystallinity can efficiently be manufactured.

(2) In the method for manufacturing a silicon carbide substrate, in the step of forming an epitaxially grown film, the base substrate may be heated while the base substrate is arranged inside the reaction chamber. Outside the reaction chamber the first gas may be mixed with the second gas,

(3) In the method for manufacturing a silicon carbide substrate, outside the reaction chamber, the first gas may be mixed with the second gas after the first gas is heated so that ammonia contained in the first gas can be thermally decomposed. Thus, a reaction gas in which the first gas and the second gas have more uniformly been mixed with each other can be supplied toward the base substrate. Consequently, a silicon carbide substrate higher in quality can be manufactured.

(4) In the method for manufacturing a silicon carbide substrate, in the step of forming an epitaxially grown film, the base substrate may he heated while the base substrate is arranged inside the reaction chamber. Inside the reaction chamber, the first gas may be mixed with the second gas.

(5) In the method for manufacturing a silicon carbide substrate, inside the reaction chamber, the first gas may be mixed with the second gas after the first gas is heated so that ammonia contained in the first gas can be thermally decomposed.

Thus, it is not necessary to provide a mechanism for heating the first gas so that ammonia contained in the first gas can be thermally decomposed separately from a mechanism for heating the base substrate. Consequently, a structure of an apparatus used for manufacturing of a silicon carbide substrate can be simplified.

(6) In the method for manufacturing a silicon carbide substrate, the halide may contain chlorine.

(7) In the method for manufacturing a silicon carbide substrate, the halide may contain silicon.

(8) In the method for manufacturing a silicon carbide substrate, the halide may include at least one of HCl, Si₂Cl₆, SiH₂Cl₂, SiHCl₃, SiCl₄, and CH₃SiCl₃.

(9) An apparatus for manufacturing a carbide substrate according to the present disclosure includes a reaction chamber for arranging abuse substrate composed of silicon carbide in the inside thereof, a heater for heating the base substrate, and a gas supplier for supplying a reaction gas for forming an epitaxially grown film on the base substrate into the inside of the reaction chamber. The gas supplier is structured to be able to supply the reaction gas in which a first gas containing ammo a and a second gas containing a halide but not containing ammonia have been mixed with each other into the inside of the reaction chamber. In addition, the gas supplier is structured to be able to mix the first gas with the second gas after the first gas is heated so that ammonia contained in the first gas can be thermally decomposed.

Since the apparatus for manufacturing a silicon carbide substrate according to the present disclosure can supply a reaction gas containing ammonia which is readily thermally decomposed into the inside of the reaction chamber, a silicon carbide substrate more uniform in impurity (nitrogen atoms) concentration can he manufactured. Since the apparatus for manufacturing a silicon carbide substrate can supply a reaction gas containing a halide into the inside of the reaction chamber, a rate of epitaxial growth can be improved. Furthermore, the apparatus for manufacturing a silicon carbide substrate can form a gas mixture by mixing a first gas containing ammonia with a second gas containing a halide after the first gas is heated so that ammonia contained in the first gas can be thermally decomposed. Therefore, generation of a solid by-product (ammonium halide) as a result of reaction between ammonia in the first gas and a halide in the second gas before they are thermally decomposed can he suppressed. Thus, lowering in crystallinity of a silicon carbide substrate due to adhesion of the by-product to a growing epitaxial film can be suppressed. Therefore, according to the apparatus for manufacturing a silicon carbide substrate according to the present disclosure, a silicon carbide substrate excellent in uniformity in impurity concentration and crystallinity can efficiently be manufactured.

(10) In the apparatus for manufacturing a silicon carbide substrate, the gas supplier may include a pre-heater arranged outside the reaction chamber, for heating the first gas so that ammonia contained in the first gas can be thermally decomposed.

Thus, a reaction gas in which the first gas and the second gas have more uniformly been mixed with each other can be supplied toward the base substrate arranged inside the reaction chamber. Consequently, a silicon carbide substrate higher in quality can be manufactured.

(11) In the apparatus for manufacturing a silicon carbide substrate, the gas supplier may include a first gas pipe having a portion located inside the reaction chamber, for supplying the first gas into the inside of the reaction chamber and a second gas pipe for supplying the second gas into the inside of the reaction chamber.

Thus, inside the reaction chamber, the first gas can be heated so that ammonia contained in the first gas can be thermally decomposed and the first gas can be mixed with the second gas after the first gas is heated. Consequently, it is not necessary to separately provide a mechanism for heating the first gas so that ammonia contained in the first gas can be thermally decomposed separately from a heater for heating the base substrate, and a structure of the apparatus can be simplified.

(12) In the apparatus for manufacturing a silicon carbide substrate, the halide may contain chlorine.

(13) In the apparatus for manufacturing a silicon carbide substrate, the halide may contain silicon.

(14) In the apparatus for manufacturing a silicon carbide substrate, the halide may include at least one of HCl, Si₂Cl₆, SiH₂Cl₂, SiHCl₃, SiCl₄, and CH₃SiCl₃.

### Details of Embodiments

Embodiments will be described hereinafter with reference to the drawings. The same or corresponding elements in the drawings below have the same reference characters allotted and the description thereof will not be repeated.

### First Embodiment

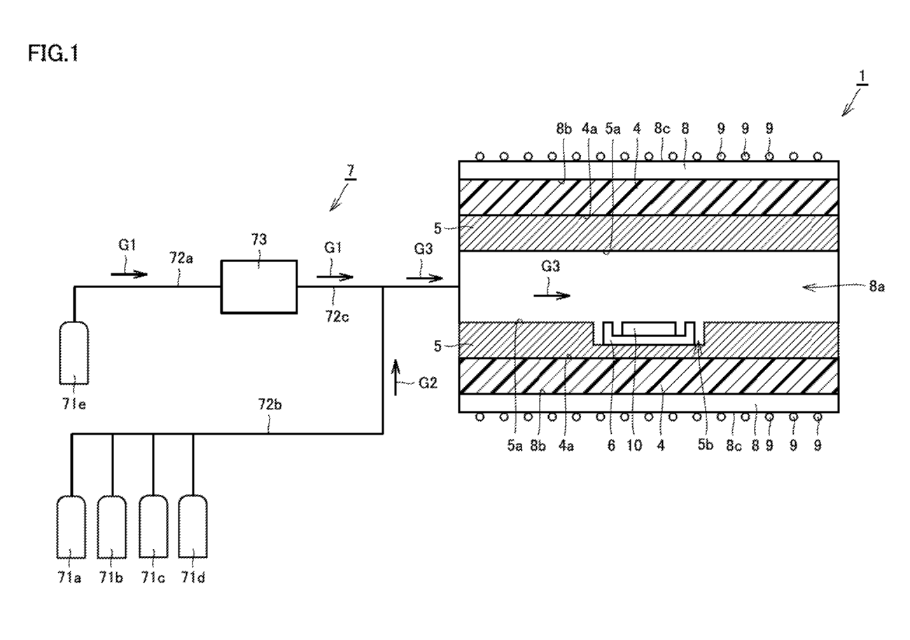

A structure of an apparatus for manufacturing a silicon carbide substrate according to a first embodiment will initially be described. As shown in FIG. 1, a chemical vapor deposition (CVD) apparatus 1 representing an apparatus for manufacturing a silicon carbide substrate according to the present embodiment is an apparatus for manufacturing a silicon carbide substrate by forming an epitaxially grown film on a base substrate 10 composed of silicon carbide. CVD apparatus 1 mainly includes a quartz tube 8 (a reaction tube), a radio frequency (RF) coil 9 (a heater), a heat insulating material 4, a heating element 5, a susceptor 6, and a gas supplier 7.

Quartz tube 8 is, for example, in a cylindrical shape, and has a reaction chamber 8a for arranging base substrate 10 therein. Quartz tube is structured such that a reaction gas for epitaxial growth is supplied through one opening (on the left in the figure) into reaction chamber 8a and the reaction gas is exhausted through the other opening (on the right in the figure).

RF coil 9 is a member for heating a reaction gas supplied to base substrate 10 and into reaction chamber 8a. RF coil 9 is arranged as being wound around an outer circumferential surface 8c of quartz tube 8, and beats heating element 5 arranged inside quartz tube 8 through high-frequency induction heating. More specifically, by supplying a high-frequency current to RF coil 9 from a power supply (not shown), varying magnetic lines of force are generated around RF coil 9, and with variation in magnetic lines of force, an eddy current flows through heating element 5. As the eddy current flows, resistance heat is generated and heating element 5 is heated. Thus, a reaction gas supplied to base substrate 10 arranged on susceptor 6 and into reaction chamber 8a can be heated.

Heat insulating material 4 is a member for thermally insulating reaction chamber 8a and the outside of quartz tube 8 from each other, and arranged along an inner circumferential surface 8b of quartz tube 8. Heat insulating material 4 is made, for example, of carbon.

Heating element 5 is made of a conductive material which can be heated through induction heating with RF coil 9, and it is made, for example, of carbon. Heating element 5 is arranged along an inner circumferential surface 4a of heat insulating material 4. Therefore, quartz tube 8, heat insulating material 4, and heating element 5 are arranged in the order of heating element 5, heat insulating material 4, and quartz tube 8 in a radial direction of quartz tube 8 (a direction from a central portion toward an outer circumferential portion). A recess 5b for arranging susceptor 6 is formed in a portion of heating element 5 including an inner circumferential surface 5a.

Susceptor 6 is a member for arranging base substrate 10 as being in contact therewith. Susceptor 6 is made, for example, of carbon, and a surface thereof is coated with silicon carbide (SiC) or tantalum carbide (TaC). Susceptor 6 is arranged. in recess 5b formed in apart of beating element 5.

Gas supplier 7 is a member for supplying a reaction gas for forming an epitaxially grown film on base substrate 10 into the inside of reaction chamber 8a. Gas supplier 7 mainly has gas cylinders 71a to 71e, gas pipes 72a to 72c, and a pre-heater 73.

Gas cylinder 71a is filled with a hydrogen (H₂) gas representing a carrier gas. Gas cylinders 71b and 71c are filled with a silane (SiH₄) gas and a propane (C₃H₈) gas representing source materials for epitaxial growth of silicon carbide, respectively. Gas cylinder 71d is filled with a hydrogen chloride (HCl) gas. Gas cylinder 710 is filled with an ammonia (NH₃) gas representing a dopant gas.

Each of gas cylinders 71a to 71d is connected to gas pipe 72b. Each of gases filled in gas cylinders 71a to 71d is supplied into gas pipe 72b by opening and closing a valve (not shown) provided in each gas cylinder. Gas cylinder 71e is connected to gas pipe 72a. The NH₃ gas filled in gas cylinder 71e is supplied to pre-heater 73 through gas pipe 72a.

Pre-heater 73 is arranged outside reaction chamber 8a. Pre-heater 73 is provided, for example, with an induction heating coil and a heating element (not shown), and heats the NH₃ gas (a first gas G1) supplied through gas pipe 72a to a thermal decomposition temperature (not lower than 800° C. and not higher than 1000° C.) of NH₃.

Gas pipe 72c has one end portion (on the left in the figure) connected to pre-heater 73 and the other end portion (on the right in the figure) connected to an end portion of quartz tube 8. Gas pipe 72c is connected to gas pipe 72b. Thus, a gas (a second gas G2) containing H₂, SiH₄, and C₃H₈ and a halide such as HCl but not containing NH₃ can be mixed with first gas G1 at a portion of connection between gas pipe 72b and gas pipe 72c. A reaction gas G3 obtained by mixing first gas G1 and second gas G2 with each other can be supplied into the inside of reaction chamber 8a through gas pipe 72c. A halide may contain chlorine or silicon. A halide may include at least one of HCl, Si₂Cl₆, SiH₂Cl₂, SiHCl₃, SiCl₄, and CH₃SiCl₃.

As above, CVD apparatus 1 according to the present embodiment includes reaction chamber 8a for arranging base substrate 10 composed of silicon carbide in the inside thereof RF coil 9 for heating base substrate 10, and gas supplier 7 supplying reaction gas G3 for forming an epitaxially grown film on base substrate 10 into the inside of reaction chamber 8a. Gas supplier 7 is structured to be able to supply reaction gas G3 in which first gas G1 containing NH₃ and second gas G2 containing such a halide as HCl but not containing Nth have been mixed with each other into the inside of reaction chamber 8a. In addition, gas supplier 7 is structured to be able to mix first gas G1 with second gas G2 after first gas G1 is heated so that NH₃ contained in first gas G1 can be thermally decomposed by pre-heater 73.

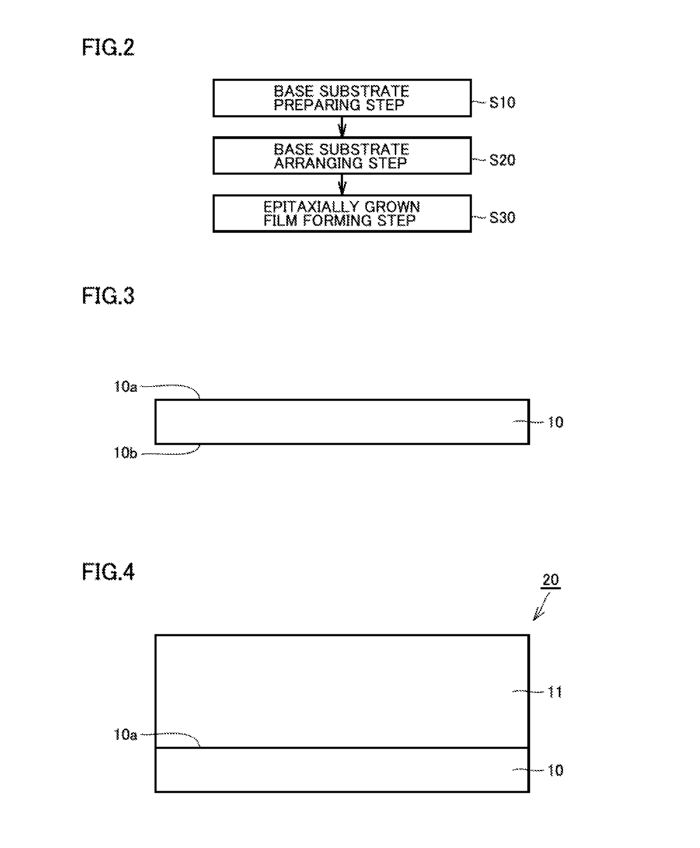

A method for manufacturing a silicon carbide substrate according to the present embodiment will now be described. The method for manufacturing a silicon carbide substrate according to the present embodiment is performed with CVD apparatus 1 representing the apparatus for manufacturing a silicon carbide substrate according to the present embodiment. As shown in FIG. 2, initially, in a step (S10), a base substrate preparing step is performed. In this step (S10), as shown in FIG. 3, base substrate 10 composed of silicon carbide and having a front surface 10a and a backside surface 10b is prepared, for example, by slicing an ingot (not shown composed of hexagonal silicon carbide of a 4H type.

Then, in a step (S20), a base substrate arranging step is performed. In this step (S20), as shown in FIG. 1, base substrate 10 prepared in the step (S10) is arranged on susceptor 6 of CVD apparatus 1.

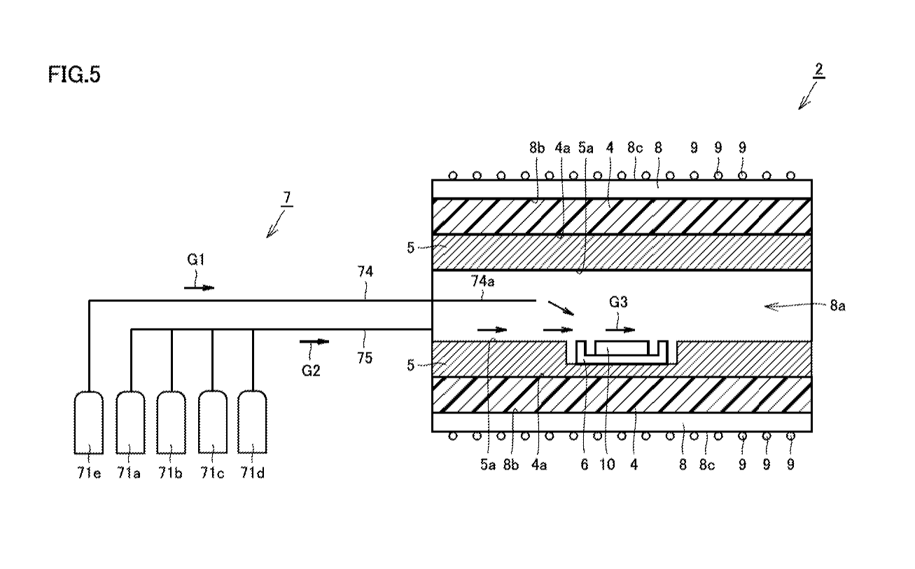

Then, in a step (S30), epitaxially grown film forming step is performed, in this step (S30), as will be described below, an epitaxially grown film 11 is formed on front surface 10a of base substrate 10 (see FIG. 4). Namely, epitaxial growth is carried out in reaction chamber 8a.

As shown in FIG. 1, initially, a valve (not shown) provided in each of gas cylinders 71a to 71e is opened. Thus, second gas G2 containing H₂, SiH₄, and C₃H₈ and containing such a halide as HCl but not containing NH₃ is supplied into gas pipe 72b, and first gas G1 containing NH₃ is supplied into gas pipe 72a. A halide may contain chlorine or silicon. A halide may include at least one of HCl, Si₂Cl₆, SiH₂Cl₂, SiHCl₃, SiCl₄, and CH₃SiCl₃.

Then, first gas G1 is supplied to pre-heater 73 through as pipe 72a. Then, pre-heater 73 heats first gas G1 to a thermal decomposition temperature (not lower than 800° C. and not higher than 1000° C.) of NH₃. Namely, outside reaction chamber 8a, first gas G1 is heated so that ammonia contained in the first gas can be thermally decomposed. Thus, at least sonic of NH₃ contained in first gas G1 or more preferably the entire NH₃ is thermally decomposed. Then, thermally decomposed first gas G1 and second gas G2 are mixed with each other in gas pipe 72c to thereby form reaction gas G3.

Then, reaction gas G3 is supplied into the inside of reaction chamber 8a through gas pipe 72c. Here, reaction chamber 8a of quartz tube 8 and base substrate 10 arranged in reaction chamber 8a have been heated to a prescribed temperature in advance by heating element 5 heated by RF coil 9. Then, as reaction gas G3 is heated by heating element 5, SiH₄ and C₃H₅ in reaction gas G3 are thermally decomposed. Consequently, as shown in FIG. 4, epitaxially grown film 11 doped with nitrogen (N) atoms and composed of silicon carbide is formed on front surface 10a of base substrate 10. Thus, as the steps (S10) to (S30) are performed, a silicon carbide substrate 20 having base substrate 10 and epitaxially grown film 11 is manufactured and the method for manufacturing a silicon carbide substrate according to the present embodiment is completed.

As above, the method for manufacturing a silicon carbide substrate according to the present embodiment includes the steps of preparing base substrate 10 composed of silicon carbide (S10), arranging prepared base substrate 10 (S20), and firming epitaxially grown film 11 on base substrate 10 (S30). In the step (S30), base substrate 10 is heated while reaction gas G3 in which first gas G1 containing NH₃ and second gas G2 containing such a halide as HCl but not containing NH₃ have been mixed with each other is supplied toward base substrate 10. First gas G1 is mixed with second gas G2 in gas pipe 72c after first gas G1 is heated so that NH₃ contained in the first gas can be thermally decomposed by pre-heater 73.

Thus, since reaction gas G3 containing NH₃ which is readily thermally decomposed is employed in the method for manufacturing a silicon carbide substrate according to the present embodiment, silicon carbide substrate 20 more uniform in nitrogen atom concentration can be manufactured. Since reaction gas G3 containing such a halide as HCl is employed in the method for manufacturing a silicon carbide substrate according to the present embodiment a rate of epitaxial growth can be improved. Furthermore, in the method for manufacturing a silicon carbide substrate according to the present embodiment, reaction gas G3 is formed by mixing first gas G1 containing NH₃ with second gas G2 containing such a halide as HCl after first gas G1 is heated so that NH₃ contained in the first gas can be thermally decomposed, Therefore, generation of NH₄Cl representing a solid by-product due to reaction between NH₃ in first gas G1 and a halide such as HCl in second gas G2 before they are thermally decomposed can be suppressed. Thus, lowering in crystallinity of the silicon carbide substrate due to adhesion of the by-product to a growing epitaxial can be suppressed. Therefore, according to the method for manufacturing a silicon carbide substrate according to the present embodiment, silicon carbide substrate 20 excellent in uniformity in impurity concentration and crystallinity can efficiently be manufactured.

In the step (S30), base substrate 10 may be heated while it is arranged inside reaction chamber 8a Outside reaction chamber 8a, first gas G1 may be mixed with second gas G2. More specifically, first gas G1 may be mixed with second gas G2 at the portion of connection between gas pipe 72b and gas pipe 72c as shown in FIG. 1, after first gas G1 is heated so that NH₃ contained in the first gas can be thermally decomposed by pre-heater 73 arranged outside reaction chamber 8a.

Thus, reaction gas G3 in which first gas G1 and second gas G2 have more uniformly been mixed with each other than in a case that first gas G1 and second gas G2 are mixed with each other inside reaction chamber 8a can be supplied toward base substrate 10. Consequently, silicon carbide substrate 20 higher in quality can be manufactured.

### Second Embodiment

A structure of a CVD apparatus 2 representing an apparatus for manufacturing a silicon carbide substrate according to a second embodiment will now be described CVD apparatus 2 according to the present embodiment is structured basically similarly to CVD apparatus 1 according to the first embodiment, and achieves a similar effect. CVD apparatus 2 according to the present embodiment, however, is different from CVD apparatus 1 according to the first embodiment in structure of gas supplier 7.

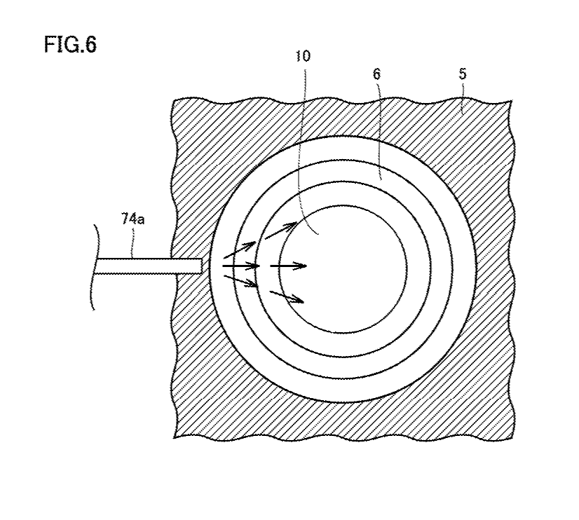

As shown in FIG. 5, in CVD apparatus 2, gas supplier 7 mainly has gas cylinders 71a to 71e, a first gas pipe 74, and a second gas pipe 75. As in the first embodiment, gas cylinders 71a to 71e are filled with the H₂ gas, the SiH₄ gas, the C₃H₈ gas, the HCl gas, and the NH₃ gas, respectively. Each of gas cylinders 71a to 71d is connected to second gas pipe 75, and gas cylinder 71e is connected to first gas pipe 74. Thus, second gas G2 containing H₂, and C₃H₈ and a halide such as HCL but not containing NH₃ can be supplied into second gas pipe 75 and first gas G1 containing NH₃ can be supplied into first gas pipe 74.

First gas pipe 74 is a member for supplying first gas G1 into the inside of reaction chamber 8a and connected to the end portion of quartz tube 8 at one end portion (on the right in the figure). First gas pipe 74 has an insertion portion 74a which is a portion located inside quartz tube 8 (a portion of quartz tithe 8 opposed to heating element 5). Namely, as shown in FIG. 5, first gas pipe 74 has one end portion (on the right in the figure) inserted in the inside of reaction chamber 8a. Thus, first gas G1 which flows through insertion portion 74a can be heated so that NH₃ contained in the first gas can be thermally decomposed by RF coil 9 and heating element 5. Second gas pipe 75 is a member for supplying second gas G2 into the inside of reaction chamber 8a and has one end portion on the right in the figure) connected to the end portion of quartz tube 8.

As shown in FIGS. 5 and 6, first gas pipe 74 has been inserted in the inside of reaction chamber 8a such that one end portion is not located above susceptor 6. Namely, first gas pipe 74 is arranged such that one end portion is located upstream of susceptor 6 in a direction of flow of reaction gas G3. Thus, a prescribed interval can be held between one end portion of first gas pipe 74 including a port for supply of first gas G1 and base substrate 10. Consequently, first gas G1 can be supplied toward base substrate 10 while first gas G1 is more uniformly diffused (arrows in FIG. 6).

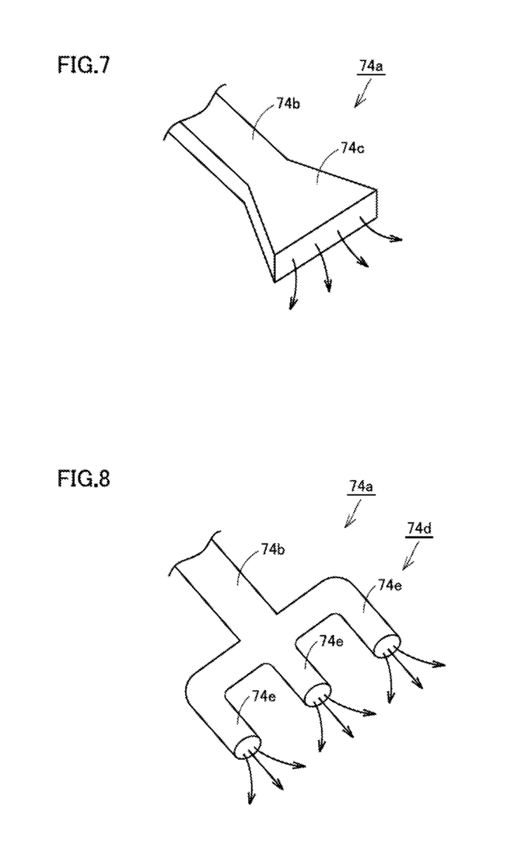

As shown in FIG. 7, insertion portion 74a may have a gas flow path 74b forming a flow path for the first gas and a gas supply port 74c shaped to gradually increase in width toward a tip end portion. Insertion portion 74a may be greater in cross-sectional area at as supply port 74c than at gas flow path 74b. Thus, uniform diffusion of the first gas inside the quartz tube is further facilitated. A cross-sectional shape of insertion portion 74a at gas supply port 74c is not limited to a rectangular shape as shown in FIG. 7, and it can be in any other shape (for example, an annular shape, a square shape, and other polygonal shapes).

As shown in FIG. 8, insertion portion 74a may have gas flow path 74b forming a flow path for the first gas and a gas supply port 74d including a plurality of branch portions 74e. Thus, as in the description with reference to FIG. 7, uniform diffusion of the first gas inside reaction chamber 8a is further facilitated. The number of branch portions 74e may be set to 3 as shown in FIG. 8, however, the number can be selected as appropriate without being limited thereto. A cross-sectional shape of insertion portion 74a at each branch portion 74e is not limited to an annular shape as shown in FIG. 8, and for example, any other shape such as a rectangular shape can be adopted. Branch portions 74e may be formed to extend along one another as shown in FIG. 8, however, an orientation of each branch portion 74e can also be selected as appropriate so as to more uniformly diffuse the first gas.

A method for manufacturing a silicon carbide substrate according to the present embodiment will now be described. As shown in FIG. 2, initially, as in the first embodiment, the base substrate preparing step (S10) and the base substrate arranging step (S20) are performed. Thus, base substrate 10 composed of silicon carbide is arranged on susceptor 6 of CVD apparatus 2 (see FIG. 5).

Then, in the step (S30), the epitaxially grown film forming step is performed. In this step (S30), as described below, epitaxially grown film 11 is formed on base substrate 10 as in the first embodiment (see FIG. 4).

As shown in FIG. 5, initially, a valve (not shown) provided in each of gas cylinders 71a to 71e is opened. Thus, second gas G2 containing H₂, SiH₄, and C₃H₈ and containing such a halide as HCl but not containing NH₃ is supplied into second gas pipe 75, and first gas G1 containing NH₃ is supplied into first gas pipe 74.

Then, first gas G1 supplied into insertion portion 74a of first gas pipe 74 is heated to a temperature not lower than the thermal decomposition temperature of NH₃ by RF coil 9 and heating element 5. Namely, inside reaction chamber 8a, first gas G1 is heated so that NH₃ contained in the first gas can be thermally decomposed. Thus, at least some of NH₃ contained in first gas G1 or more preferably the entire NH₃ is thermally decomposed. Second gas G2 supplied into reaction chamber 8a through second gas pipe 75 is similarly heated by RF coil 9 and heating element 5. Thus, SiH₄ and C₃H₈ in second gas G2 are thermally decomposed. Then, as thermally decomposed first gas G1 and second gas G2 are mixed with each other in reaction chamber 8a, reaction gas G3 is formed, and reaction gas G3 is supplied toward base substrate 10. Then, epitaxially grown film 11 doped with nitrogen atoms is formed on front surface 10a of heated base substrate 10 (see FIG. 4). Thus, as the steps (S10) to (S30) are performed, as in the first embodiment, silicon carbide substrate 20 having base substrate 10 and epitaxially grown film 11 is manufactured, and the method for manufacturing a silicon carbide substrate according to the present embodiment is completed.

As described above, in the method for manufacturing a silicon carbide substrate according to the present embodiment, as in the first embodiment, first gas G1 is mixed with second gas G2 after first gas G1 is heated so that NH₃ contained in the first gas can be thermally decomposed. Therefore, generation of a by-product (NH₄Cl) due to reaction between NH₃ contained in first gas G1 and HCl contained in second gas G2 can be suppressed and resultant lowering in crystallinity of the silicon carbide substrate can be suppressed.

In the method for manufacturing a silicon carbide substrate according to the present embodiment, unlike the first embodiment, base substrate 10 is heated while it is arranged inside reaction chamber 8a and first gas G1 is mixed with second gas G2 after first gas G1 is heated inside reaction chamber 8a. More specifically, first gas G1 is mixed with second gas G2 after first gas G1 is heated so that NH₃ contained in the first gas can be thermally decomposed by RE coil 9 and heating element 5 for heating base substrate 10. Therefore, it is not necessary to separately provide a mechanism (pre-heater 73) for heating first gas G1 as in the first embodiment, and a structure of the apparatus can be simplified.

### Third Embodiment

A structure of a CVD apparatus 3 representing an apparatus for manufacturing a silicon carbide substrate according to a third embodiment will now be described. CVD apparatus 3 according to the present embodiment is structured basically similarly to CVD apparatuses 1 and 2 according to the first and second embodiments, and achieves a similar effect. CVD apparatus 3 according to the present embodiment, however, is different from CVD apparatuses 1 and 2 according to the first and second embodiments in structure of heating element 5 and gas supplier 7.

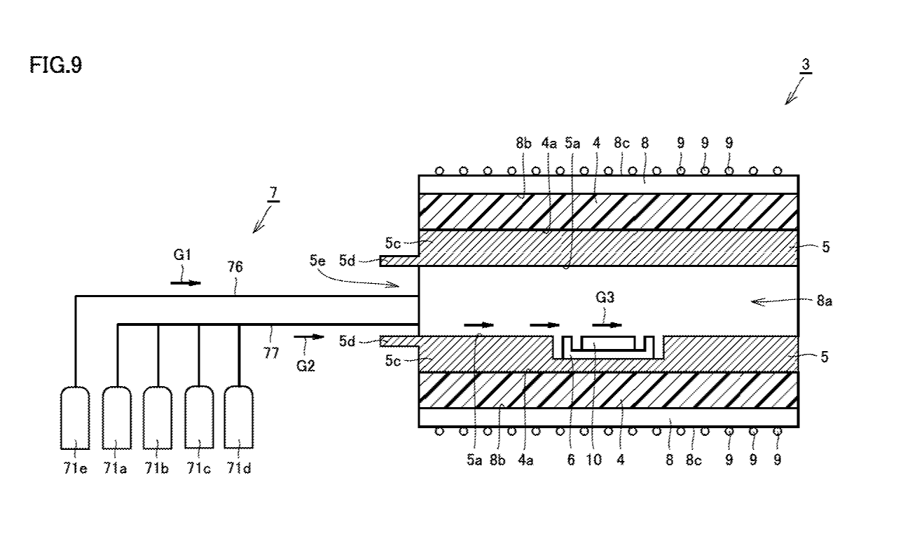

As shown in FIG. 9, in CVD apparatus 3, gas supplier 7 is basically the same in structure as the second embodiment. Namely, second gas G2 containing H₂, SiH₄, and C₃H₈ and a halide such as HCL but not containing NH₃ can be supplied into a gas pipe 77 and first gas G1 containing NH₃ can be supplied into a gas pipe 76. Gas pipes 76 and 77 are connected to the end portion of quartz tube 8 at one end portions (on the right in the figure). Here, in the present embodiment, gas pipe 76 is connected to quartz tube 8 without being inserted into the inside of quartz tube 8 (a portion of quartz tube 8 opposed to a heating element main body 5c).

Heating element 5 includes heating element main body 5c and an annular protruding portion (guide portion) 5d formed to protrude in an axial direction at one end portion of beating element main body 5c (an end portion on a side of gas pipes 76 and 77). A pre-heating region 5e is formed on an inner circumferential side of guide portion 5d, and gas pipes 76 and 77 are arranged in pre-heating region 5e. Therefore, by heating pre-heating region 5e located on the inner circumferential side of guide portion 5d with RF coil 9, gas pipes 76 and 77 located in pre-heating region 5e can be heated. Thus, first gas G1 supplied into gas pipe 76 can be heated so that NH₃ contained in the first gas can be thermally decomposed in pre-heating region 5e. Namely, unlike the second embodiment, first gas G1 can be pre-heated not inside a portion of quartz tube 8 opposed to heating element main body 5c but outside that portion (pre-heating region 5e).

A method for manufacturing a silicon carbide substrate according to the present embodiment will now be described. As shown in FIG. 2, initially, as in the first and second embodiments, the base substrate preparing step (S10) and the base substrate arranging step (S20) are performed. Thus base substrate 10 composed of silicon carbide is arranged on susceptor 6 of CVD apparatus 3 (see FIG. 9).

Then, in the step (S30), the epitaxially grown film forming step is performed. In this step (S30), as described below, epitaxially grown film 11 is formed on base substrate 10 as in the first and second embodiments (see FIG. 4).

As shown in FIG. 9, initially, a valve (not shown) provided in each of gas cylinders 71a to 71e is opened. Thus, second gas G2 containing H₃, SiH₄, and C₃H₈ and containing such a halide as HCl but not containing NH₃ is supplied into gas pipe 77, and first gas G1 containing NH₃ is supplied into gas pipe 76.

Then, first gas G1 supplied into gas pipe 76 is heated to a temperature not lower than the thermal decomposition temperature of NH₃ by RF coil 9 and guide portion 5d of heating element 5 as first gas G1 passes through pre-heating region 5e. Thus, at least some of NH₃ contained in first gas G1 or more preferably the entire NH₃ is thermally decomposed in pre-heating region 5e. At least some of SiH₄ and C₃H₈ in second gas G2 is thermally decomposed as second gas G2 supplied into gas pipe 77 is also similarly heated in pre-heating region 5e. Then, as first gas G1 and second gas G2 are mixed with each other in reaction chamber 8a, reaction gas G3 is formed, and reaction as G3 is supplied toward base substrate 10. Then, epitaxially grown film 11 doped with nitrogen atoms is firmed on front surface 10a of heated base substrate 10 (see FIG. 4). Thus, as the steps (S10) to (S30) are performed, as in the first and second embodiments, silicon carbide substrate 20 having base substrate 10 and epitaxially grown film 11 is manufactured, and the method for manufacturing a silicon carbide substrate according to the present embodiment is completed.

As described above, in the method for manufacturing a silicon carbide substrate according to the present embodiment, as in the first and second embodiments, first gas G1 is mixed with second gas G2 after first gas G1 is heated so that NH₃ contained in the first gas can be thermally decomposed. Therefore, generation of a by-product (NH₄Cl) due to reaction between NH₃ contained in first gas G1 and HCl contained in second gas G2 can be suppressed and resultant lowering in crystallinity of the silicon carbide substrate can be suppressed.

In the method for manufacturing a silicon carbide substrate according to the present embodiment, first gas G1 is heated so that NH₃ contained in the first gas can be thermally decomposed in pre-heating region 5e by guide portion 5d formed in heating element 5 and thereafter mixed inside reaction chamber 8a, with second gas G2. Therefore, it is not necessary to separately provide pre-heater 73 as in the first embodiment, and first gas G1 can be pre-heated before being mixed with second gas G2 without inserting a gas pipe into the inside of reaction chamber 8a as in the second embodiment. Thus, melt of a gas pipe by heat in reaction chamber 8a due to insertion of the gas pipe into the inside of reaction chamber 8a can be prevented.

It should be understood that the embodiments disclosed herein are illustrative and non-restrictive in every respect. The scope of the present invention is defined by the terms of the claims, and is intended to include any modifications within the scope and meaning equivalent to the terms of the claims.

What is claimed:

1. A method for manufacturing a silicon carbide substrate, in which epitaxial growth is carried out in a reaction chamber, comprising the steps of:
arranging a base substrate composed of silicon carbide in said reaction chamber; and
forming an epitaxially grown film on said base substrate,
in said step of forming an epitaxially grown film,
said base substrate being heated while a reaction gas in which a first gas containing ammonia and a second gas containing a halide but not containing ammonia have been mixed with each other is supplied toward said base substrate, and
said first gas being mixed with said second gas after said first gas is heated so that ammonia contained in said first gas can be thermally decomposed.

2. The method for manufacturing a silicon carbide substrate according to claim 1, wherein
in said step of forming an epitaxially grown film, said base substrate is heated while said base substrate is arranged inside said reaction chamber, and outside said reaction chamber, said first gas is mixed with said second gas.

3. The method for manufacturing a silicon carbide substrate according to claim 2, wherein
outside said reaction chamber, said first gas is heated so that ammonia contained in said first gas can be thermally decomposed.

4. The method for manufacturing a silicon carbide substrate according to claim 1, wherein
in said step of forming an epitaxially grown film, said base substrate is heated while the base substrate is arranged inside said reaction chamber, and inside said reaction chamber, said first gas is mixed with said second gas.

5. The method for manufacturing a silicon carbide substrate according to claim 4, wherein
inside said reaction chamber, said first gas is heated so that ammonia contained in said first gas can be thermally decomposed.

6. The method for manufacturing a silicon carbide substrate according to claim 1, wherein
said halide contains chlorite.

7. The method for manufacturing a silicon carbide substrate according to claim 1, wherein
said halide contains silicon.

8. The method for a manufacturing a silicon carbide substrate according to claim 1, wherein
said halide includes at least one of HCl, Si₂Cl₆, SiH₂Cl₂, SiCl₄, and CH₃SiCl₃.

9. An apparatus for manufacturing a silicon carbide substrate, comprising:
a reaction chamber for arranging a base substrate composed of silicon carbide in inside;
a heater for heating said base substrate; and
a gas supplier for supplying a reaction gas for forming an epitaxially grown film on said base substrate into the inside of said reaction chamber,
said gas supplier being structured to be able to supply said reaction gas in which a first gas containing ammonia and a second gas containing a halide but not containing ammonia have been mixed with each other into the inside of said reaction chamber, and structured to be able to mix said first gas with said second gas after said first gas is heated so that ammonia contained in said first gas can be thermally decomposed.

10. The apparatus for manufacturing a silicon carbide substrate according to claim 9, wherein
said gas supplier includes a pre-heater arranged outside said reaction chamber, for heating said first gas so that ammonia contained in said first gas can be thermally decomposed.

11. The apparatus for manufacturing a silicon carbide substrate according to claim 9, wherein
said gas supplier includes a first gas pipe having a portion located inside said reaction chamber, for supplying said first gas into the inside of said reaction chamber and a second gas pipe for supplying said second gas into the inside of said reaction chamber.

12. The apparatus for manufacturing a silicon carbide substrate according to claim 9, wherein
said halide contains chlorine.

13. The apparatus for manufacturing a silicon carbide substrate according to claim 9, wherein
said halide contains silicon.

14. The apparatus for manufacturing a silicon carbide substrate according to claim 9, wherein
said halide includes at least one of HCl, Si₂Cl₆, SiH₂Cl₂, SiHCl₃, SiCl₄, and CH₃SiCl₃.
